(19) United States
(12) Patent Application Publication
(10) Pub. No.: US 2009/0184746 A1
(43) Pub. Date: Jul. 23, 2009

(54) Low Voltage Drop Unidirectional Electronic Valve

(75) Inventor: Shawn Anthony FAHRENBRUCH, Tustin, CA (US)

Correspondence Address: MICROSEMI CORP - AMSG LTD., C/O LANDONIP, INC, 1700 DIAGONAL ROAD, SUITE 450, ALEXANDRIA, VA, 22202-3709, US

(73) Assignee: MICROSEMI CORPORATION, Garden Grove, CA (US)

(21) Appl. No.: 12/348,002

(22) Filed: Jan. 1, 2009

Related U.S. Application Data
(60) Provisional application No. 61/022,515, filed on Jan. 22, 2008.

(51) Int. Cl. H03K 17/687

(52) U.S. Cl. 327/427

(57) ABSTRACT

A low voltage drop unidirectional electronic valve constituted of: a first terminal; a second terminal; an electronically controlled switch arranged to allow the flow of current from the first terminal to the second terminal when closed, the electronically controlled switch comprising a pair of reverse serially connected field effect transistors; a control circuit, arranged to close the electronically controlled switch responsive to the potential of the first terminal exceeding the potential of the second terminal by a predetermined amount; and a refresh circuit arranged to periodically open the electronically controlled switch. In one embodiment the low voltage drop unidirectional valve is arranged as one of a solar bypass element and an ORing diode.

### CROSS-REFERENCE TO RELATED APPLICATIONS

This application claims priority from U.S. Provisional Patent Application Ser. No. 61/022,515 filed Jan. 22, 2008, of the same title, the entire contents of which are incorporated herein by reference.

### BACKGROUND

The invention relates generally to the field of unidirectional electronic valves, and more particularly to a low voltage drop unidirectional electronic valve operating as a near ideal diode.

Solar power for large scale use, and/or for feeding into a power grid, is typically supplied by an array of serially connected solar panels. Each solar panel exhibits a positive terminal, and a return, or negative terminal. Solar panels generate electricity in the presence of an appropriate amount of sunlight, and thus one solar panel in the array may be in a dark condition, while others may be generating electricity. The dark condition may be caused by, among others, a flying object or bird, a cloud covering, or accumulated dirt. Electricity must be bypassed around the dark solar panel so that the output of the array is not blocked. Similarly, in the event of a failure of a single solar panel in the array, electricity must be bypassed around the failed solar panel so as to avoid failure of the entire array.

FIG. 1A illustrates an example of a technique known to the prior art to avoid failure of a solar array due to a dark or failed solar panel. The solar power arrangement of FIG. 1A comprises a plurality of solar panels 10, a plurality of bypass diodes 20, a blocking diode 30 and a converter 40. Solar panels 10 are connected serially, with the positive terminal of the ultimate solar panel 10 connected to the input of converter 40 via blocking diode 30. The return of converter 40 is connected to the return terminal of the first solar panel 10 of the arrangement. Each solar panel 10 has connected in parallel thereto a bypass diode 20, arranged to conduct only when the return terminal of the solar panel 10 to which it is connected exhibits a positive potential in relation to the positive terminal of that solar panel 10 in accordance with IEC 61215, published by the International Electrotechnical Commission, Geneva, Switzerland, and in particular section 10.18, the entire contents of IEC 61215 is incorporated herein by reference.

In operation, a dark solar panel 10 will exhibit a voltage reversal between the positive terminal and return terminal as a result of the current being driven into the return terminal from the positive terminal of the preceding solar panel 10. This voltage reversal rises to turn on the parallel connected bypass diode 20, thereby passing current around the dark solar panel 10.

The arrangement of FIG. 1A is successful in maintaining an output despite a dark solar panel; however the power dissipation of a bypass diode 20 is substantial. In a typical solar panel array, such as the arrangement of FIG. 1A, approximately 5-10 Amperes are flowing through each of the solar panels 10 in the array. Thus the power dissipation of a bypass diode 20, when operative as a bypass, is on the order of 3.5-7 Watts. The power lost to the system is emitted as heat, which thus drives thermal considerations for panel layout, construction of bypass diode 20 and ultimately cost of the arrangement of FIG. 1A.

Power sources, not necessarily solar panel sources, are often combined by an ORing diode, as shown in FIG. 1B, in which a first and second power source are supplied to a single load by way of a pair of ORing diodes. The power supply exhibiting the larger voltage potential will drive the single load however power is lost due to the voltage drop across the ORing diode.

There is thus a long felt need for a low voltage drop unidirectional electronic valve, preferably adaptable for use as one of a solar panel bypass element and an ORing diode.

### SUMMARY OF THE INVENTION

Accordingly, it is a principal object of the present invention to overcome the disadvantages of prior art unidirectional electronic valves. This is provided in certain embodiments by an electronically controlled switch comprising a pair of reverse serially connected field effect transistors arranged to block current flow when the electronically controlled switch is open and unidirectionally pass current when the electronically controlled switch is closed responsive to a control circuit. Power for the switch and the control circuit is taken from a voltage reversal, and held by a capacitor. Preferably, the electronically controlled switch comprises a pair of field effect transistors (FETs), further preferably metal oxide silicon FETs (MOSFETs), further preferably n-channel MOSFETS, connected so that their internal body diodes do not present a through path for electricity in either direction between the return terminal and positive terminal. The pair of MOSFETS, in cooperation with the control circuit, represents a near ideal diode.

Responsive to the voltage reversal, the electronically controlled switch is closed, thereby enabling unidirectional current flow with a minimal voltage drop, preferably less than 0.1 volts. Periodically, the electronically controlled switch is opened thereby allowing the voltage reversal to rise thereby refreshing the circuit.

Additional features and advantages of the invention will become apparent from the following drawings and description.

### BRIEF DESCRIPTION OF THE DRAWINGS

For a better understanding of the invention and to show how the same may be carried into effect, reference will now be made, purely by way of example, to the accompanying drawings in which like numerals designate corresponding elements or sections throughout.

With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. In the accompanying drawings:

FIG. 1A illustrates a high level block diagram of a solar power arrangement comprising a serially connected solar panel array, each exhibiting a bypass diode, in accordance with the prior art;

FIG. 1B illustrates a high level block diagram of a pair of ORing diodes providing power from a pair of sources to a single load, in accordance with the prior art;

FIG. 2 illustrates a high level block diagram of an embodiment of a solar power arrangement comprising a serially connected solar panel array, each exhibiting a low voltage drop unidirectional electronic valve arranged as a bypass element;

FIG. 3 illustrates a schematic representation of an implementation of the low voltage drop unidirectional electronic valve of FIG. 2;

FIG. 4 illustrates a schematic representation of an implementation of the low voltage drop unidirectional electronic valve arranged as a bypass element of FIG. 2 with an additional comparing circuit to identify operation of the solar panel;

FIG. 5A illustrates a high level flow chart of a method of operation of the low voltage drop unidirectional electronic valve of FIG. 3;

FIG. 5B illustrates a high level flow chart of a method of operation of the comparing circuit of FIG. 4; and

FIG. 6 illustrates the voltage across the low voltage drop unidirectional electronic valve of FIGS. 2 and 3.

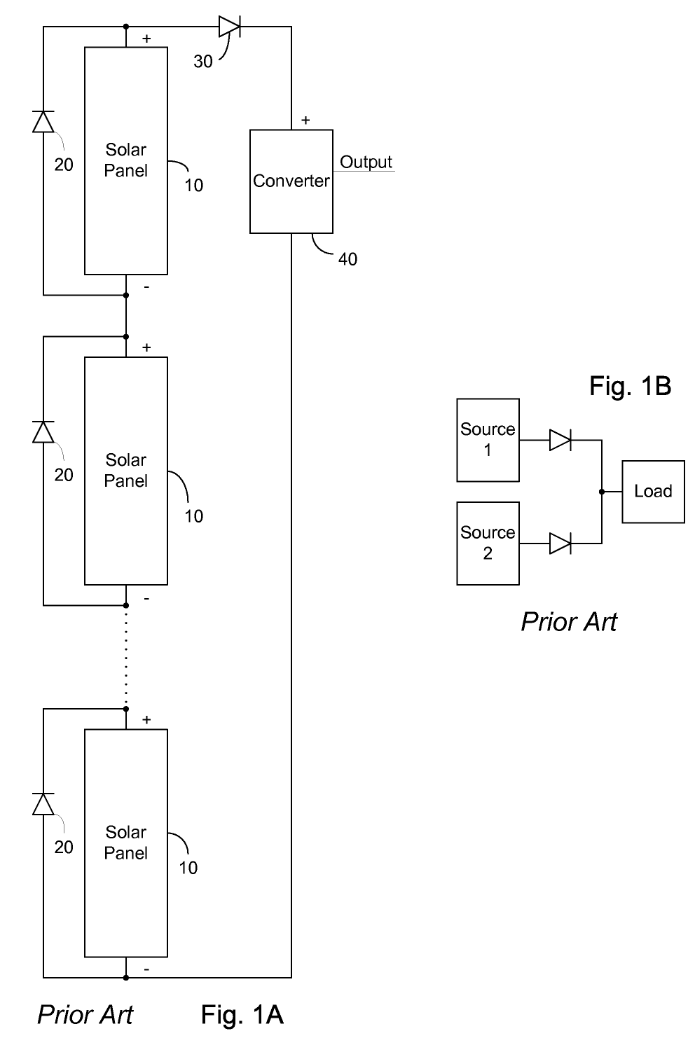

### DETAILED DESCRIPTION OF THE PREFERRED EMBODIMENTS

The present embodiments enable a low voltage drop unidirectional electronic valve comprising a pair of reverse serially connected field effect transistors arranged to block current flow when the electronically controlled switch is open and unidirectionally pass current when the electronically controlled switch is closed. Periodically, the electronically controlled switch is opened thereby refreshing the circuit.

Before explaining at least one embodiment of the invention in detail, it is to be understood that the invention is not limited in its application to the details of construction and the arrangement of the components set forth in the following description or illustrated in the drawings. The invention is applicable to other embodiments or of being practiced or carried out in various ways. Also, it is to be understood that the phraseology and terminology employed herein is for the purpose of description and should not be regarded as limiting.

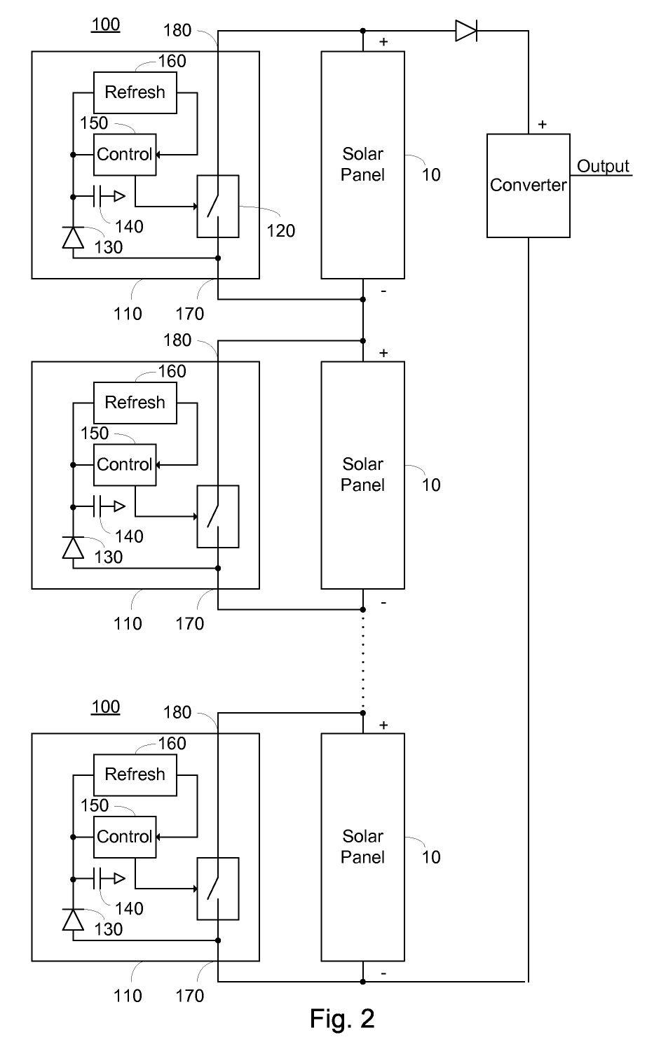

FIG. 2 illustrates a high level block diagram of a solar power arrangement 100 comprising a serially connected array of solar panels 10, each exhibiting a low voltage drop unidirectional electronic valve 110 arranged as a bypass element, in accordance with a principle of the invention, each low voltage drop unidirectional electronic valve 110 comprising an electronically controlled switch 120, a one way electronic valve 130, an electronic storage means 140, a control circuit 150 a periodic refresh circuit 160, a first terminal 170 and a second terminal 180. One way electronic valve 130 is illustrated as a diode, and will be described in relation thereto, without being limiting in any way. Electronic storage means 140 is illustrated as a capacitor, and will be described in relation thereto, without being limiting in any way.

First terminal 170 of each low voltage drop unidirectional electronic valve 110 is connected to a first end of respective electronically controlled switch 120, the anode of diode 130 and the return terminal of a respective solar panel 10. Second terminal 180 of each low voltage drop unidirectional electronic valve 110 is connected to a second end of respective electronically controlled switch 120 and the positive terminal of a respective solar panel 10. The cathode of diode 130 is connected to a first end of capacitor 140, an input of control circuit 150 and the input of refresh circuit 160. The output of refresh circuit 160 is connected to an input of control circuit 150, and the output of control circuit 150 is connected to the control input of electronically controlled switch 120. A second end of capacitor 140 is connected to a common point.

In normal operation of solar panel 10 the potential of the positive terminal is greater than the potential of the return terminal. In the event that control circuit 150 senses that the potential at the return terminal of the respective solar panel 10, connected to first terminal 170, is greater than the potential at the positive terminal of the respective solar panel 10, connected to second terminal 180, by at least a predetermined amount, control circuit 150 acts to close the respective electronically controlled switch 120. Current then flows via electronically controlled switch 120, which preferably exhibits a voltage drop of less than 0.1 volts. Periodically, refresh circuit 160 acts to open electronically controlled switch 120, and in the event that respective solar panel 10 is not operative, the potential of the return terminal of the solar panel 10 begins to rise in relation to the positive terminal until it again exceeds the predetermined amount described above. Power for the operation of control circuit 150, electronically controlled switch 120 and refresh circuit 160 is provided by the combination of diode 130 and capacitor 140.

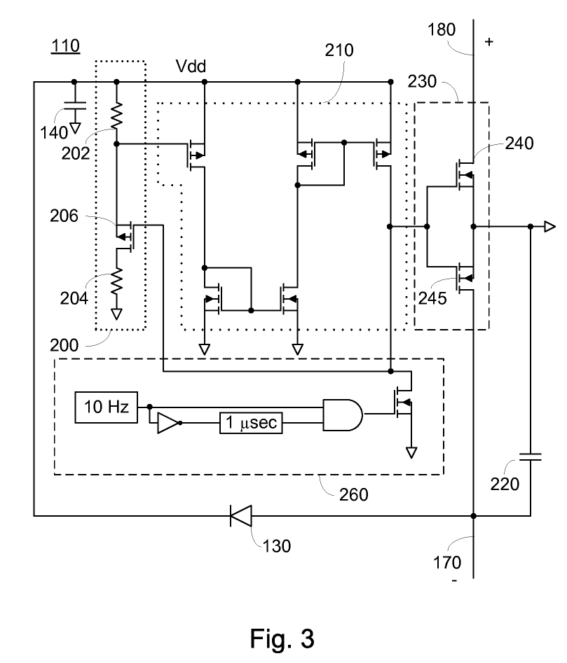

FIG. 3 illustrates a schematic representation of an implementation of low voltage drop unidirectional electronic valve 110 of FIG. 2 comprising: a one way electronic valve 130, a capacitor 140, a first terminal 170, a second terminal 180, an under voltage lock out (UVLO) circuit 200, an amplifier 210, a slowing capacitor 220, an electronically controlled switch 230 implemented with a pair of MOSFETs 240, 245 and a refresh circuit 260. One way electronic valve 130 is illustrated as a diode, and will be described in relation thereto.

UVLO circuit 200 comprises: a first resistor 202, a second resistor 204 and a MOSFET 206. A first end of UVLO circuit 200, coincident with a first end of first resistor 202, is connected to the cathode of diode 130 and to a first end of capacitor 140 and is denoted Vdd. A second end of capacitor 140 is connected to a common point. A second end of first resistor 202 is connected to the source of MOSFET 206, implemented as a P-channel MOSFET, denoted hereinafter as a PMOSFET, and the drain of MOSFET 206 is connected to a first end of second resistor 204. A second end of UVLO circuit 200, coincident with a second end of second resistor 204, is connected to the common point. UVLO circuit 200 is thus implemented as a voltage divider controlled by a MOSFET connected between the resistors of the voltage divider.

The second end of resistor 202, representing the voltage divided point of UVLO circuit 200, is connected to the gate of the input to amplifier 210. When MOSFET 206 is conducting, voltage is dropped across first resistor 202 thereby turning on amplifier 210, particularly by the gate of the first MOSFET of amplifier 210, implemented as a PMOSFET, being at a lower potential than the source thereof connected to Vdd.

Amplifier 210 amplifies the voltage drop across first resistor 202 and drives the gates of MOSFETs 240, 245, implemented as N-channel MOSFETs, denoted hereinafter as NMOSFETs, to nearly the potential of Vdd, which is operative to turn on MOSFETs 240, 245. The output of amplifier 210 further is connected to the gate of MOSFET 206, thus shutting off MOSFET 206 when electronically controlled switch 230 is closed. UVLO circuit 200 is thus inactive when electronically controlled switch 230 is closed.

Slowing capacitor 220 is connected at a first end to the common point and at a second end to first terminal 170 and is operative to prevent a rapid change in voltage across first terminal 170 in reference to the common point, thereby protecting the integrity of UVLO circuit 200 and amplifier 210.

Electronically controlled switch 230 is constituted of a pair of reverse serially connected field effect field transistors, preferably MOSFETs, and more particularly as NMOSFETs 240, 245. The sources of MOSFETs 240, 245 are connected together and the drains represent the respective terminals of electronically controlled switch 230. In particular, the drain of NMOSFET 240 is connected to second terminal 180, and the source of NMOSFET 240 is connected to the common point, a first end of slowing capacitor 220, and the source of NMOSFET 245. The drain of NMOSFET 245 is connected to first terminal 170 and to the second end of slowing capacitor 220. Advantageously, the reverse serial arrangement of NMOSFET 240 and NMOSFET 245 does not present a path via the inherent body diodes from first terminal 170 to/from second terminal 180 when electronically controlled switch 230 is open.

Refresh circuit 260, implemented with a slow oscillator of 10 Hz, and a 1 microsecond delay line, provides a refresh pulse of about 10 microseconds every 100 milliseconds. The output of refresh circuit 260, constituted of an NMOSFET, is connected to the gates of NMOSFETs 240, 245, and is arranged so that the refresh pulse connects the gates of NMOSFETs 240, 245 to the common point. The refresh pulse is thus operative to open electronically controlled switch 230 and enable UVLO circuit 200 via MOSFET 206.

In operation, when current attempts to enter via terminal 170, and exit via terminal 180, when electronically controlled switch 230 is open, the potential of terminal 170 will rise in respect to the common point, charging both slowing capacitor 220 and capacitor 140 via diode 130. MOSFET 206 is closed, thereby creating a resistor ladder between resistors 202, 204 and energizing amplifier 210 to close electronically controlled switch 230 by driving the gates of NMOSFET 240, 245 towards Vdd, and the voltage drop across low voltage drop unidirectional electronic valve 110 then drops below 0.1 volts. MOSFET 206 is then opened preventing current drain of the charge stored on capacitor 140.

Periodically, refresh circuit 260 opens electronically controlled switch 230, and enables UVLO circuit 200 by closing MOSFET 206. This causes the voltage at first terminal 170 to increase as current again attempts to enter via first terminal 170, thereby recharging capacitor 140 and ultimately again closing electronically controlled switch 230 via amplifier 210.

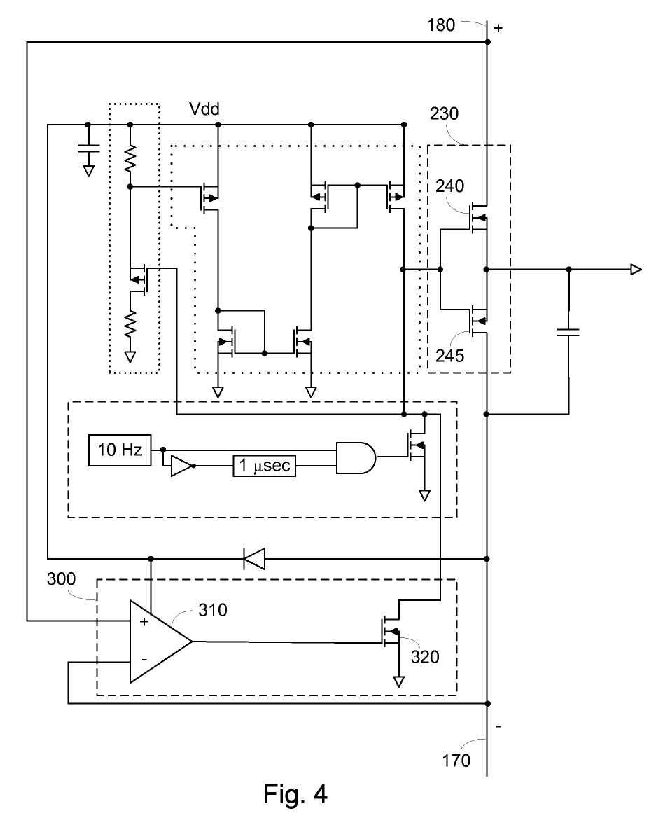

FIG. 4 illustrates a schematic representation of an implementation of the low voltage drop unidirectional electronic valve 110 of FIG. 2, implemented as a bypass element, with an additional comparing circuit 300 to identify operation of the solar panel. The circuit of FIG. 4 is in all respects identical with the circuit of FIG. 3, with the addition of comparing circuit 300, which will now be described.

Comparing circuit 300 comprises a comparator 310 and a NMOSFET 320. The source of NMOSFET 320 is connected to the common point, and the drain of NMOSFET 320 is connected to the gates of NMOSFET 240, 245. Power for comparator 310 is provided from Vdd. The non-inverting input of comparator 310 is connected to second terminal 180 and the inverting input of comparator 310 is connected to first terminal 170.

In operation, when solar panel 10 of FIG. 2 begins to function, the potential of second terminal 180 becomes positive in relation to the potential of first terminal 170. Responsive to second terminal 180 becoming positive in relation to the potential of first terminal 170, comparator 310 opens electronically controlled switch 230 via NMOSFET 320.

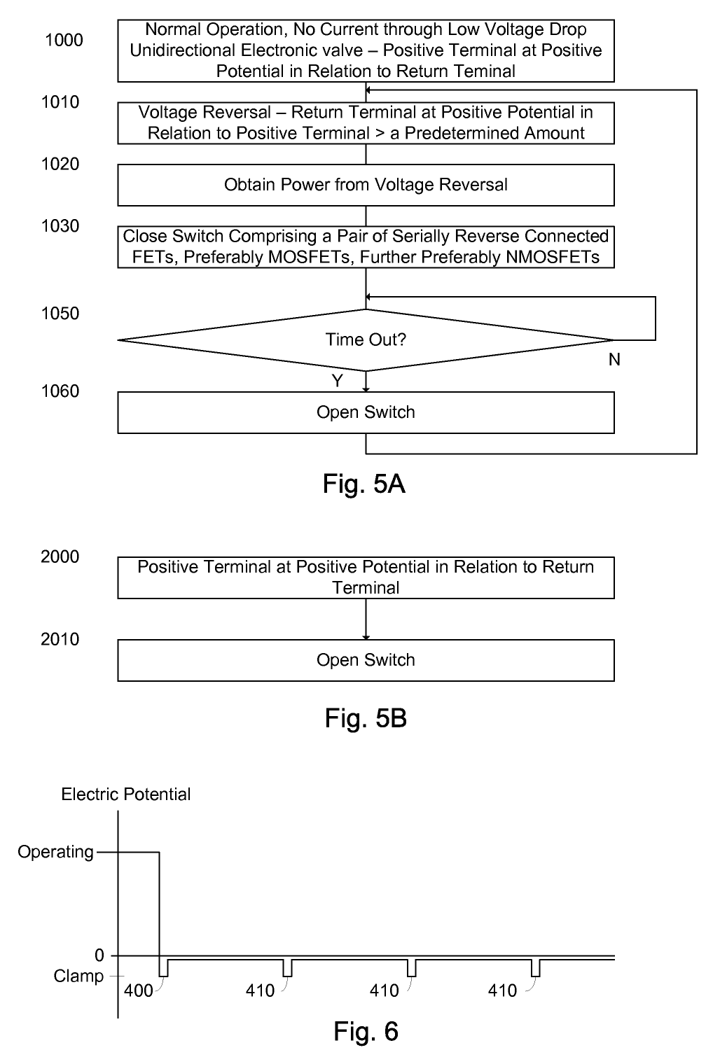

FIG. 5A illustrates a high level flow chart of a method of operation of the circuit of FIG. 3. In stage 1000, normal closed operation occurs, in which no current is to pass through the low voltage drop unidirectional electronic valve. In an embodiment in which the low voltage drop unidirectional electronic valve is arranged as a bypass element, as illustrated in relation to FIG. 2, stage 1000 is representative of the positive terminal of the solar panel at a positive electric potential in relation to the return terminal. In stage 1010 a voltage reversal is detected, i.e. the electric potential of the return terminal becomes positive by at least a predetermined amount in relation to the positive terminal.

In stage 1020, power is obtained from the voltage reversal. In stage 1030, electronically controlled switch 230 is closed, thereby enabling current flow with a low voltage drop, preferably less than 0. 1 volts. Electronically controlled switch 230 comprises a pair of reverse serially connected field effect transistors, preferably FETs, further preferably MOSFETs, as described above in relation to FIG. 3. The voltage drop across the low voltage drop unidirectional electronic valve is thus less than the predetermined amount of stage 1010. In stage 1050, a periodic timer is checked. In the event that the timer has expired, in stage 1060, electronically controlled switch 230 is opened, thereby refreshing the voltage reversal.

FIG. 5B illustrates a high level flow chart of a method of operation of the comparing circuit of FIG. 4. In stage 2000, the electric potential at the nominally positive terminal, for example the terminal connected to the positive terminal of the solar panel which is to be bypassed is sensed as positive in relation to the return terminal of the solar panel, indicative of operation of the solar panel. In stage 2010, electronically controlled switch 230 is opened, thereby disabling the bypass element to allow for normal operation.

FIG. 6 illustrates the voltage potential across the bypass element of FIGS. 2 and 3, in which the x-axis indicates time and the y-axis indicates the difference of potential between the nominally positive terminal, for example the terminal for connection to the positive terminal of solar panel 10, coincident with second terminal 180 of low voltage drop unidirectional electronic valve 110, and first terminal 170 of low voltage drop unidirectional electronic valve 110.

At the beginning of operation, the electric potential of second terminal 180 is positive in relation to the potential of first terminal 170, indicative of proper operation of solar panel 10. Solar panel 10 ceases to operate, and the potential difference reverses to the operating point of UVLO circuit 200, as indicated by negative step 400. Responsive to the closing of electronically controlled switch 230, the potential difference becomes more positive than preferably −0.1 volt, equivalent to the voltage drop across electronically controlled switch 230 when fully closed.

Periodically, refresh pulses 410 are exhibited, in which the potential difference falls to a predetermined voltage, and then again responsive to the closing of electronically controlled switch 230, the potential difference becomes more positive than preferably −0.1 volt.

Thus, the present embodiments enable an electronically controlled switch comprising a pair of reverse serially connected field effect transistors arranged to block current flow when the electronically controlled switch is open and unidirectionally pass current when the electronically controlled switch is closed responsive to a control circuit. Power for the switch and the control circuit is taken from a voltage reversal, and held by a capacitor. Preferably, the electronically controlled switch comprises a pair of field effect transistors (FETs), further preferably metal oxide silicon FETs (MOSFETs), further preferably n-channel MOSFETS, connected so that their internal body diodes do not present a through path for electricity in either direction between the return terminal and positive terminal. The pair of MOSFETS, in cooperation with the control circuit, represents a near ideal diode.

Responsive to the voltage reversal, the electronically controlled switch is closed, thereby enabling unidirectional current flow with a minimal voltage drop, preferably less than 0.1 volts. Periodically, the electronically controlled switch is opened thereby allowing the voltage reversal to rise thereby refreshing the circuit.

The above has been described in relation to a bypass diode for a solar panel, however this is not meant to be limiting in any way. In one embodiment a diode in accordance with the teaching of the invention is used as an ORing diode, thereby avoiding the wasted energy of the diode drop.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

Unless otherwise defined, all technical and scientific terms used herein have the same meanings as are commonly understood by one of ordinary skill in the art to which this invention belongs. Although methods similar or equivalent to those described herein can be used in the practice or testing of the present invention, suitable methods are described herein.

All publications, patent applications, patents, and other references mentioned herein are incorporated by reference in their entirety. In case of conflict, the patent specification, including definitions, will prevail. In addition, the materials, methods, and examples are illustrative only and not intended to be limiting.

The terms “include”, “comprise” and “have” and their conjugates as used herein mean “including but not necessarily limited to”.

It will be appreciated by persons skilled in the art that the present invention is not limited to what has been particularly shown and described hereinabove. Rather the scope of the present invention is defined by the appended claims and includes both combinations and sub-combinations of the various features described hereinabove as well as variations and modifications thereof, which would occur to persons skilled in the art upon reading the foregoing description.

I claim:

1. A low voltage drop unidirectional electronic valve, comprising:
a first terminal;
a second terminal;
an electronically controlled switch arranged to allow the flow of current from said first terminal to said second terminal when closed, said electronically controlled switch comprising a pair of reverse serially connected field effect transistors;
a control circuit, arranged to close said electronically controlled switch responsive to the potential of said first terminal exceeding the potential of said second terminal by a predetermined amount; and
a refresh circuit arranged to periodically open said electronically controlled switch.

2. A low voltage drop unidirectional electronic valve according to claim 1, wherein each of said field effect transistors of said pair is constituted of an identical type of metal oxide silicon field effect transistor (MOSFET), the body diode of each MOSFET being connected to the source terminal thereof.

3. A low voltage drop unidirectional electronic valve according to claim 1, wherein each of said pair of field effect transistors is constituted of an n-channel metal oxide silicon field effect transistor (MOSFET), the body diode of each MOSFET being connected to the source terminal thereof, and the source terminals of said pair being coupled together to form said reverse serial connection.

4. A low voltage drop unidirectional electronic valve according to claim 1, wherein each of said pair of field effect transistors is constituted of an n-channel metal oxide silicon field effect transistors (MOSFET), the body diode of each MOSFET being connected to the source terminal thereof, and the source terminals of said pair being coupled together to define a common electrical point and to form said reverse serial connection.

5. A low voltage drop unidirectional electronic valve according to claim 1, further comprising an electronic one way valve, wherein said first terminal is operatively connected to the anode of said electronic one way valve, the cathode of said electronic one way valve being connected to an electronic storage element, said electronic storage element providing power for said control circuit.

6. A low voltage drop unidirectional electronic valve according to claim 5, wherein said control circuit comprises an under voltage lockout circuit in communication with said cathode of said electronic one way valve, said under voltage lockout circuit being operative to close said electronic switch responsive to said potential of said first terminal exceeding said second terminal by said predetermined amount.

7. A low voltage drop unidirectional electronic valve according to claim 1, further comprising a comparing circuit operatively connected to said first terminal and said second terminal, said comparing circuit arranged to open said electronically controlled switch responsive to the potential of said second terminal exceeding the potential of said first terminal.

8. A low voltage drop unidirectional electronic valve according to claim 1, wherein said low voltage drop unidirectional electronic valve is arranged as one of a solar panel bypass element and an ORing element.

9. A method of enabling a low voltage drop unidirectional current flow, the method comprising:
providing an electronically controlled switch comprising a pair of reverse serially connected field effect transistors;
sensing the electric potential of a first terminal exceeding the electric potential of a second terminal by at least a predetermined value;
closing said provided electronically controlled switch responsive to said sensed potential of the first terminal exceeding the potential of the second terminal by at least said predetermined value, said closing said electronically controlled switch reducing said difference in potential to less than said predetermined value; and
periodically opening said electronically controlled switch thereby enabling said potential of said first terminal to exceed the potential of said second terminal by at least said predetermined value.

10. A method according to claim 9, further comprising obtaining and storing power for said periodical opening from said first terminal when said potential of the first terminal exceeds the potential of the second terminal by said at least a predetermined value.

11. A method according to claim 9, wherein said electronically controlled switch functions as an ideal diode switch.

12. A method according to claim 9, further comprising:
comparing the electric potential of the first terminal to the electric potential of the second terminal; and
opening, in the event the electric potential of the second terminal exceeds the electric potential of the first terminal, said electronically controlled.

13. A method according to claim 9, wherein said pair of field effect transistors are constituted of an identical type of metal oxide silicon field effect transistors (MOSFET), the body diode of each MOSFET being connected to the source terminal thereof.

14. A method according to claim 9, wherein each of said pair of field effect transistors is constituted of an n-channel metal oxide silicon field effect transistor (MOSFET), the body diode of each MOSFET being connected to the source terminal thereof, and the source terminals of said pair being coupled together forming said reverse serial connection.

15. A solar panel assembly comprising a solar panel and a bypass element, said bypass element comprising:
a first terminal connected to the return terminal of the solar panel;
a second terminal connected to the positive terminal of the solar panel;
an electronically controlled switch arranged to allow the flow of current from said first terminal to said second terminal when closed, said electronically controlled switch comprising a pair of reverse serially connected field effect transistors;
a control circuit, arranged to close said electronically controlled switch responsive to the potential of said return terminal exceeding the potential of said positive terminal by a predetermined amount; and
a refresh circuit arranged to periodically open said electronically controlled switch.

16. A solar panel assembly according to claim 15, wherein said pair of field effect transistors are constituted of an identical type of metal oxide silicon field effect transistors (MOSFET), the body diode of each MOSFET being connected to the source terminal thereof.

17. A solar panel assembly according to claim 15, wherein each of said pair of field effect transistors is constituted of an n-channel metal oxide silicon field effect transistor (MOSFET), the body diode of each MOSFET being connected to the source terminal thereof, and the source terminals of said pair being coupled together to form said reverse serial connection.

18. A solar panel assembly according to claim 15, further comprising an electronic one way valve, wherein said first terminal is operatively connected to the anode of said electronic one way valve, the cathode of said electronic one way valve being connected to an electronic storage element, said electronic storage element providing power for said control circuit.

19. A solar panel assembly according to claim 18, wherein said control circuit comprises an under voltage lockout circuit in communication with said cathode of said electronic one way valve, said under voltage lockout circuit being operative to close said electronically controlled switch responsive said potential of said first terminal exceeding said second terminal by said predetermined amount.

20. A solar panel assembly according to claim 17, further comprising a comparing circuit operatively connected to said first terminal and said second terminal, said comparing circuit arranged to open said electronically controlled switch responsive to the potential of said second terminal exceeding the potential of said first terminal.
